(19) United States
(12) Patent Application Publication
(10) Pub. No.: US 2025/0343216 A1
(43) Pub. Date: Nov. 6, 2025

(54) PHOTONIC PACKAGES WITH MODULES AND FORMATION METHOD THEREOF

(71) Applicant: Taiwan Semiconductor Manufacturing Co., Ltd., Hsinchu (TW)

(72) Inventor: Ming-Fa Chen, Taichung (TW)

(21) Appl. No.: 19/266,610

(22) Filed: Jul. 11, 2025

Related U.S. Application Data
(63) Continuation of application No. 18/455,857, filed on Aug. 25, 2023.
(60) Provisional application No. 63/502,684, filed on May 17, 2023.

(51) Int. Cl. H01L 25/16; H01L 21/48; H01L 21/56; H01L 23/00; H01L 23/31; H01L 23/498

(52) U.S. Cl. CPC H01L 25/167; H01L 21/4853; H01L 21/565; H01L 23/3107; H01L 23/49827; H01L 23/49838; H01L 24/16; H01L 24/32; H01L 24/73; H01L 24/81; H01L 2224/16145; H01L 2224/16235; H01L 2224/32145; H01L 2224/32225; H01L 2224/73204; H01L 2224/81815; H01L 2224/81895; H01L 2224/81896; H01L 2924/1903

(57) ABSTRACT

A method includes bonding a module over a package component. The module includes a substrate and through-vias penetrating through the substrate. The method further includes molding the module in a molding compound, bonding an electronic die on the module, and bonding a photonic die over the electronic die.

### PRIORITY CLAIM AND CROSS-REFERENCE

This application is a continuation U.S. patent application Ser. No. 18/455,857, filed Aug. 25, 2023, which application claims the benefit of the following provisionally filed U.S. Patent application: Application No. 63/502,684, filed on May 17, 2023, and entitled “SiPH (silicon photonic) by CoCoS (chip-on-chip-on-substrate) Solution,” which applications are hereby incorporated herein by reference.

### BACKGROUND

Electrical signaling and processing are one of techniques for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both of optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7 illustrate the cross-sectional views of intermediate stages in the formation of a photonic package in accordance with some embodiments.

FIGS. 8-10 illustrate the cross-sectional views of some raising modules in accordance with some embodiments.

FIG. 11 illustrates a process flow for forming a photonic package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A photonic package and the method of forming the same are provided. In accordance with some embodiments, a raising module is bonded to a package substrate, and is then encapsulated in an encapsulant. The raising module includes through-vias therein. An Electronic Die (also referred to an E-die) is over and bonded to the raising module, and a photonic die (Also referred to a P-die or a PIC) may be over and bonded to the electronic die. The raising module is used to raise the height of the electric die, so that its stand-off distance from the package substrate is increased. With the use of the raising module to provide mechanical support, the electronic die can also be thin without the concern of breaking. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

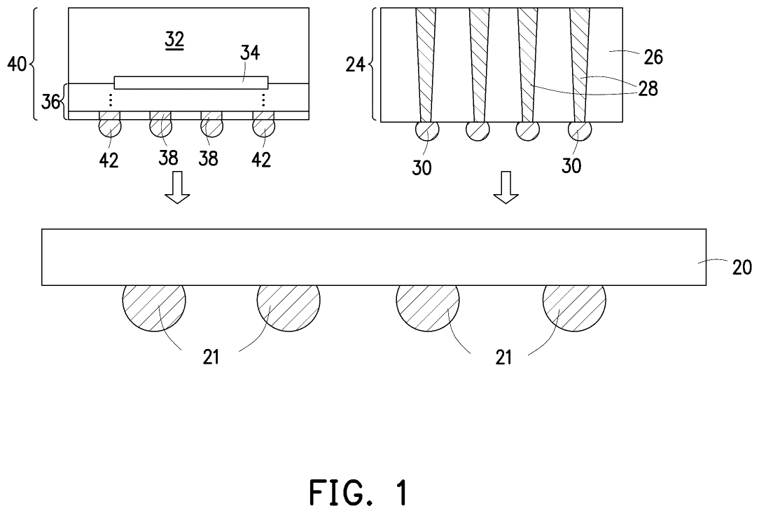

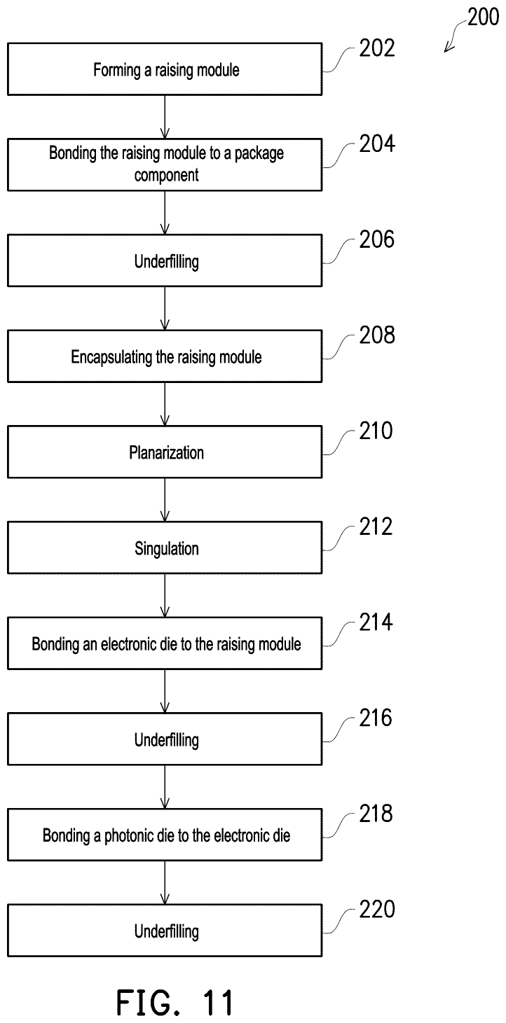

FIGS. 1 through 7 illustrate the cross-sectional views of intermediate stages in the formation of a photonic package in accordance with some embodiments. The corresponding processes are also reflected schematically in the process flow 200 as shown in FIG. 11.

Referring to FIG. 1, package component 20 is provided for attaching other package components in accordance with some embodiments. Package component 20 may include a package substrate, an interposer, a printed circuit board, a package including other package components such as device dies, or the like. Electrical conductive features (not shown) are formed on the top side and the bottom side of package component 20, and are electrically interconnected through electrical conductive paths (such as metal lines, vias, or the like, not shown) inside package component 20. When being a package substrate, package component 20 may include a plurality of dielectric layers (such as organic dielectric layers), with the redistribution lines being formed in the plurality of dielectric layers. When being an interposer, package component 20 may include a semiconductor substrate, redistribution lines (such as metal lines and vias) on opposing sides of the semiconductor substrate, and through-semiconductor vias in the semiconductor substrate to interconnect the redistribution lines on the opposing sides of the semiconductor substrate.

Raising module 24 is formed. The respective process is illustrated as process 202 in the process flow 200 as shown in FIG. 11. In accordance with some embodiments, raising module 24 includes a dielectric substrate 26, and through-vias (also referred to as through-dielectric vias or metal posts) 28 penetrating through the dielectric substrate 26. Dielectric substrate 26 may be formed of a homogeneous dielectric material, which may be an inorganic dielectric material or an organic dielectric material. For example, dielectric substrate 26 may be formed of or comprise a resin, an epoxy, silicon oxide, silicon nitride, silicon oxynitride, silicon carbonitride, a glass, or the like.

In accordance with some embodiments, through-vias 28 are formed of or comprise a metallic material such as copper, aluminum, tungsten, nickel, or the like, or alloys thereof. The top surface of through-vias 28 may be coplanar with the top surface of substrate 26, and the bottom surface of through-vias 28 may be coplanar with the bottom surface of substrate 26. In accordance with some embodiments, solder regions 30 are formed at and contact the bottom ends of through-vias 28.

In accordance with some embodiments, the formation of raising module 24 includes providing a blank substrate, etching the blank substrate to form openings, filling the openings with a metallic material, and performing a planarization process to remove excess portions of the metallic materials, so that a surface of the metallic material is coplanar with a surface of substrate 26. When the blank substrate is a dielectric substrate, through-vias 28 may be in physical contact with the substrate. When the blank substrate is a semiconductor substrate, each of through-vias 28 may be separated from the substrate by a dielectric insulation liner. Raising module 24 may be formed at wafer-level, and a sawing process may be performed to saw the respective wafer into a plurality of identical raising modules 24.

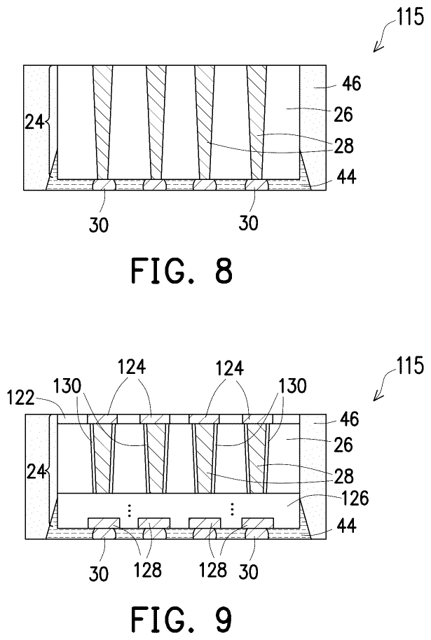

It is appreciated that the raising module 24 as shown in FIG. 1 is an example, while raising module 24 may have other structures. For example, FIGS. 8-10 illustrate some example applicable structures. In accordance with some embodiments, raising module 24 is free from active devices (such as transistors and diodes) therein, and may be free from passive devices (such as capacitors, resistors, inductors, or the like) therein.

In accordance with some embodiments, raising module 24 is free from horizontal conductive lines that have lengthwise directions parallel to the top surface of substrate 26. Alternatively stated, raising module 24 is not used for routing signals and currents/voltages horizontally. Rather, raising module 24 is used for vertical electrical connection. In accordance with some embodiments, substrate 26 is free from any conductive features other than through-vias 28 therein. In accordance with alternative embodiments, raising module 24 may include horizontal conductive lines, which reroute signals/voltages/currents horizontally.

Device die 40 is also provided. In accordance with some embodiments, device die 40 comprises a switch die for the operation of the electronic die and the photonic die that will be bonded in subsequent processes. Device die 40 may also include logic dies, memory dies (such as memory stacks), independent passive devices (IPDs) such as independent capacitor dies, packages includes device dies therein, or the like.

In accordance with some example embodiments, device die 40 includes semiconductor substrate 32, which may be a silicon substrate, and integrated circuit 34 (which may include, for example, transistors) at a surface of semiconductor substrate 32. Interconnect structure 36 is formed on semiconductor substrate 32. Interconnect structure 36 may include metal lines, vias, contact plugs, and/or the like, which are electrically connected to integrated circuit 34. Metal pads 38 and solder regions 42 may be formed at the bottom surface of device die 40, and are used for bonding.

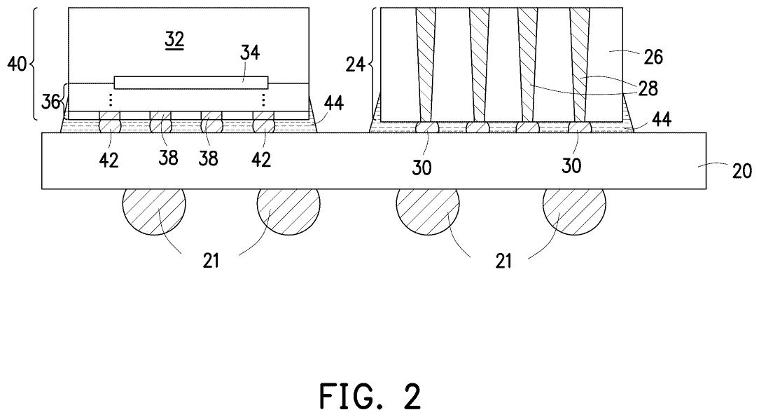

Referring to FIG. 2, raising module 24 and device die 40 are bonded to package component 20. The respective process is illustrated as process 204 in the process flow 200 as shown in FIG. 11. The bonding process may include a placement process, wherein solder regions 30 and 42 are aligned to the bond pads (not shown) of package component 20, followed by a reflow process to reflow solder regions 30 and 42. In accordance with some embodiments, the bonding process is performed at wafer-level, wherein package component 20 may be a package substrate strip including a plurality of package substrates, an interposer including a plurality of interposers, or the like. A plurality of identical raising module 24 and a plurality of device die 40 are bonded to the respective underlying package substrates, interposers or the like in package component 20.

In accordance with alternative embodiments, the bonding process is performed at the die level, wherein package component 20 is a discrete package substrate, a discrete interposer, or the like, while a single raising module 24 is bonded to the package component 20. There may be a single or a plurality of device dies 40 bonding to the same package component 20. After being bonded, device die 40 may be electrically and signally connected to through-vias 28 through the conductive paths in the package component 20.

Next, underfill 44 is dispensed into the gap between raising module 24 and the underlying package component 20, and into the gap between device die 40 and the underlying package component 20. The respective process is illustrated as process 206 in the process flow 200 as shown in FIG. 11. A curing process is then performed to cure underfill 44. Underfill 44 may include a base material such as a polymer, a resin, an epoxy, and/or the like, and filler particles (which may be formed of a dielectric material such as silica, aluminum oxide, or the like) in the base material.

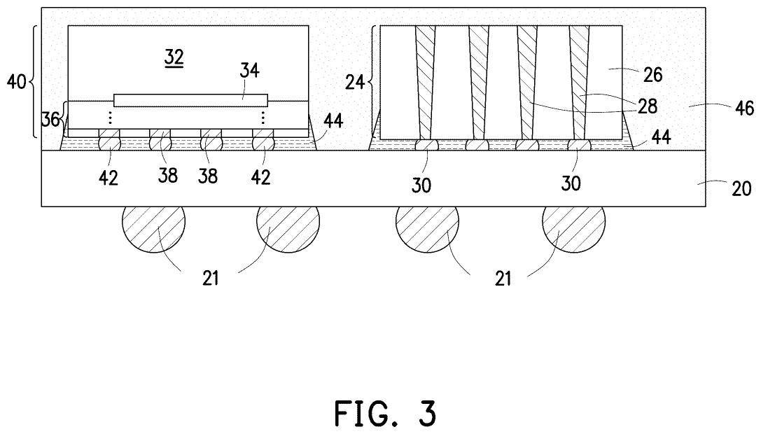

Referring to FIG. 3, an encapsulation process is performed to encapsulate raising module 24 and device die 40 in encapsulant 46. The respective process is illustrated as process 208 in the process flow 200 as shown in FIG. 11. In accordance with some embodiments, encapsulant 46 comprises a molding compound, a molding underfill, an epoxy, a resin, or the like. Encapsulant 46 may also include a base material such as a polymer, a resin, an epoxy, and/or the like, and filler particles (which may be formed of a dielectric material such as silica, aluminum oxide, or the like) in the base material.

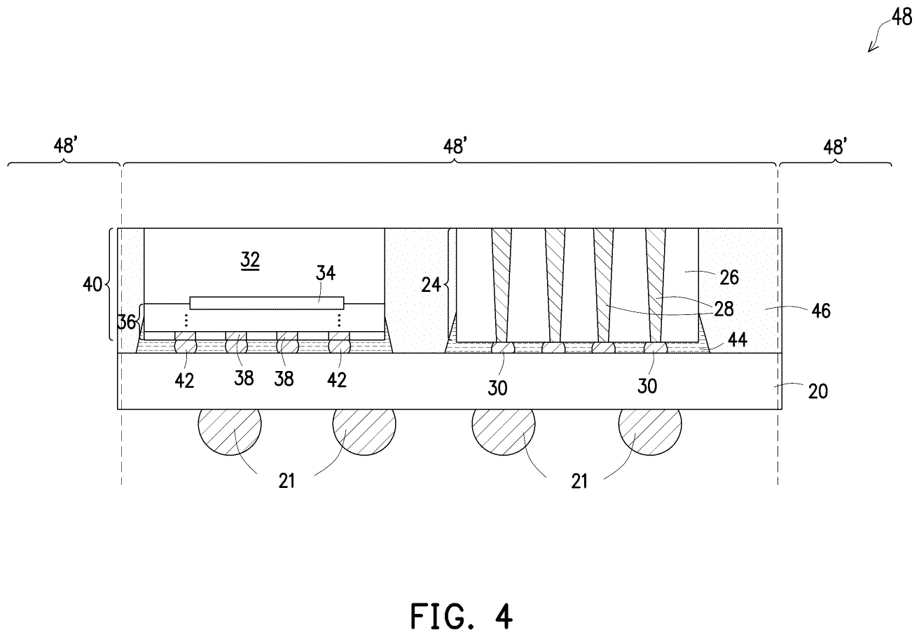

A planarization process such as a Chemical Mechanical Polish (CMP) process or a mechanical grinding process is then performed to remove excess portions of the encapsulant 46, and to reveal raising module 24. The respective process is illustrated as process 210 in the process flow 200 as shown in FIG. 11. When device die 40 comprises semiconductor substrate 32, semiconductor substrate 32 is also planarized, and the back surface of semiconductor substrate 32 is revealed. In accordance with some embodiments in which raising module 24 comprises substrate 26 (dielectric or semiconductor) and through-vias 28 having coplanar top surface, after the planarization, the top surfaces of substrate 26 and through-vias 28 are planarized and thus are coplanar with the top surface of encapsulant 46. In accordance with alternative embodiments in which raising module 24 has the structure as shown in FIG. 9, the top surface of the top conductive features 124 (such as metal pads) are revealed. Throughout the description, the structure shown in FIG. 4 is referred to as reconstructed wafer 48.

In accordance with some embodiments in which package component 20 is a wafer-level component, a singulation process is performed to saw reconstructed wafer 48 into a plurality of packages 48′, each including the raising module 24. The respective process is illustrated as process 212 in the process flow 200 as shown in FIG. 11.

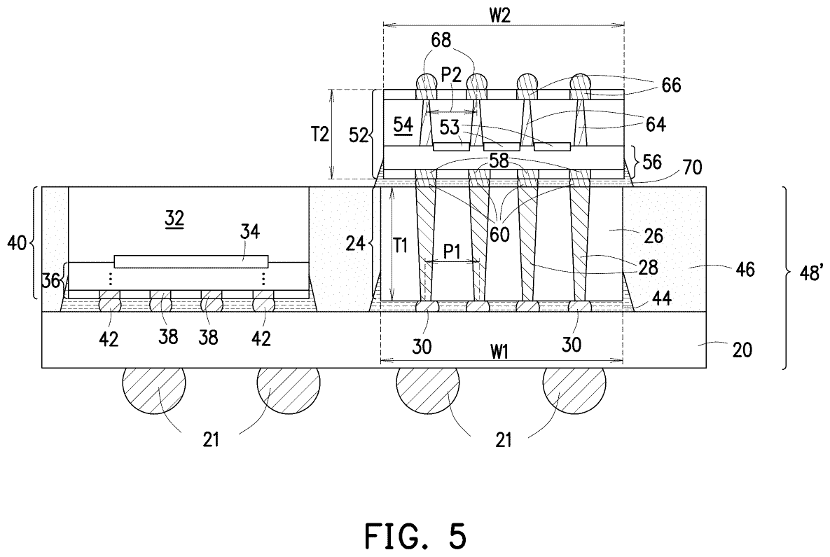

Referring to FIG. 5, electronic die 52 is bonded to package 48′, and bonded to raising module 24. The respective process is illustrated as process 214 in the process flow 200 as shown in FIG. 11. Electronic die 52 may be a semiconductor device die (chip) that communicate with photonic components using electrical signals. In accordance with some embodiments, electronic die 52 includes semiconductor substrate 54, interconnect structure 56, and electrical connectors 58, which may be, for example, conductive pads, conductive pillars, or the like. Metal pads 66 and solder regions 68 may be formed at the top surface of electronic die 52 in accordance with some embodiments.

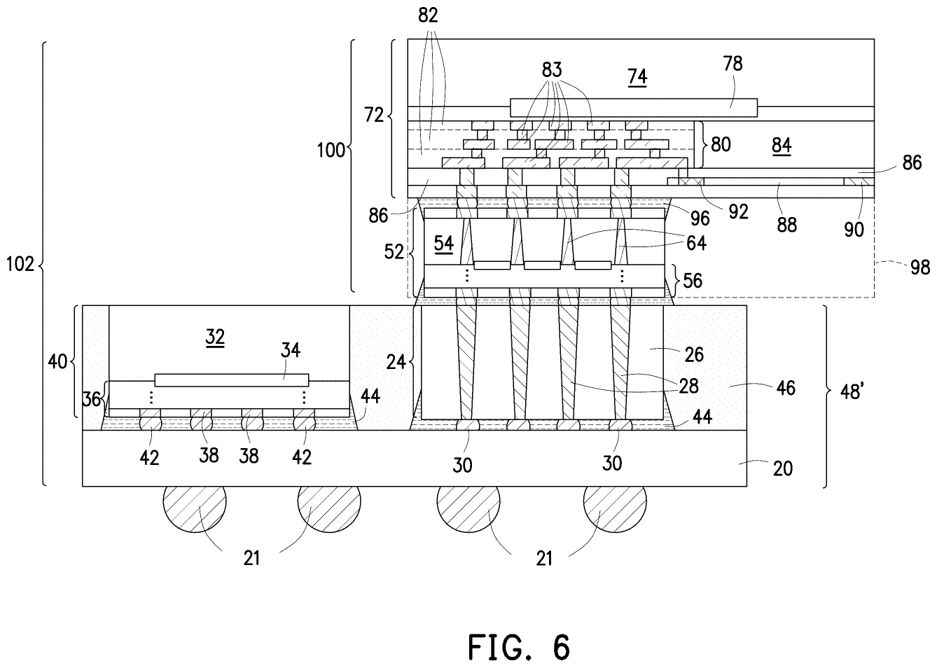

Electronic die 52 may include integrated circuits 53 for interfacing with the subsequently bonded photonic component 72 (FIG. 6, also referred to as a photonic die). Integrated circuits 53 may be the circuits for controlling the operation of photonic component 72. For example, integrated circuits 53 may include controllers, drivers, amplifiers, the like, or combinations thereof. Electronic die 52 may also include a CPU. In accordance with some embodiments, circuits 53 have the function of processing electrical signals received from photonic component 72. Electronic die 52 may also control high-frequency signaling of photonic component 72 according to electrical signals (digital or analog) received from another device or die, in accordance with some embodiments. In accordance with some embodiments, electronic die 52 may include a Serializer/Deserializer (SerDes). In this manner, electronic die 52 may act as part of an I/O interface between optical signals and electrical signals.

In accordance with some embodiments, electronic die 52 is bonded to raising module 24 through solder bonding, with solder regions 60 being used. In accordance with alternative embodiments, electronic die 52 is bonded to raising module 24 through hybrid bonding (which includes both of dielectric-to-dielectric bonding and metal-to-metal bonding), direct metal-to-metal bonding, or the like.

In accordance with some embodiments, through-vias 64 are formed to penetrate through semiconductor substrate 54. Through-vias 64 are used to electrically connect the subsequently bonded photonic die 72 (FIG. 6) to the through-vias 28 in raising module 24, and possibly to device die 40 through the conductive paths in package component 20. In accordance with some embodiments, each of through-vias 64 is electrically connected to one of through-vias 28 with a one-to-one correspondence. Furthermore, through-vias 64 may be vertically aligned to corresponding solder regions 60, corresponding through-vias 28, and corresponding solder regions 30.

The thickness T1 of raising module 24 is greater than the thickness T2 of electronic die 52. In accordance with some embodiments, the ratio T1/T2 may be greater than 1.5, greater than 2, greater than 5, and may be in the range between about 2 and about 10. Accordingly, bonding raising module 24 between electronic die 52 and package component 20, rather than bonding electronic die 52 directly to package component 20, may raise the level/height of electronic die 52. Otherwise, since electronic die 52 is thin, the subsequently bonded photonic die 72 (FIG. 6) would be too close to package component 2, and it would be difficult to align optical fiber to the edge coupler in photonic die 72. Also, since electronic die 52 is thin, and package component 20 may have a Coefficient of Thermal Expansion (CTE) significantly greater than the CTE of electronic die 52, electronic die 52 may suffer from breakage. It is appreciated that these issues cannot be solved by forming a thick electronic die 52 since thick electronic die 52 will require the lateral size of the through-vias 64 to be large, thus requiring the size of electronic die 52 to be increased.

In accordance with some embodiments, the lateral size (such as width) W1 of raising module 24 is equal to the lateral size (such as the width) W2 of electronic die 52. In accordance with alternative embodiments, the lateral size W1 of raising module 24 is greater than the lateral size W2 of electronic die 52. This may enable the size of electronic die 52 to be maintained small, while larger through-vias 28 may be formed to suit to the thicker raising module 24, so that the manufacturing process of raising module 24 is easier. In accordance with some embodiments, the pitch P1 of through-vias 28 is equal to the pitch P2 of through-vias 64. In accordance with alternative embodiments, the pitch P1 of through-vias 28 is greater than the pitch P2 of through-vias 64.

Next, underfill 70 is dispensed into the gap between electronic die 52 and the underlying package 48′. The respective process is illustrated as process 216 in the process flow 200 as shown in FIG. 11. A curing process is then performed to cure underfill 70. Underfill 70 may also include a base material such as a polymer, a resin, an epoxy, and/or the like, and filler particles (which may be formed of a dielectric material such as silica, aluminum oxide, or the like) in the base material.

In accordance with some embodiments, as shown in FIG. 5, the front side of electronic die 52 faces raising module 24, and the backside faces up. In accordance with alternative embodiments, electronic die 52 may have its front side facing up, and backside facing raising module 24.

FIG. 6 illustrates the bonding of photonic die 72 to electronic die 52 in accordance with some embodiments. The respective process is illustrated as process 218 in the process flow 200 as shown in FIG. 11. An example structure of photonic die 72 is discussed below. It is appreciated that photonic die 72 may have any other applicable structure, which is also in the scope of the present disclosure. Photonic die 72 may include substrate 74. Substrate 74 may be a semiconductor substrate, which may be a silicon substrate, a silicon germanium substrate, or a substrate formed of other semiconductor materials.

In accordance with some embodiments, integrated circuit devices 78 are formed at a front surface (the illustrated bottom surface) of substrate 74, and are used to support the functionality of the photonic die in accordance with some embodiments. Integrated circuit devices 78 may include active devices such as transistors and/or diodes. Integrated circuit devices 78 may also include passive devices such as capacitors, resistors, or the like.

Interconnect structure 80 is formed on a side of substrate 74, and may include dielectric layers 82 and metal lines and vias 83 in dielectric layers 82. In accordance with some embodiments, dielectric layers 82 are formed of silicon oxide, silicon nitride, or low-k dielectric materials, which may have dielectric constants (k values) lower than about 3.5. Metal lines and vias 83 may be formed of copper, tungsten, or the like.

In accordance with some embodiments, a part of the dielectric layers 82 in the interconnect structure 80 is removed through etching, and is then replaced with a light-transparent dielectric region 84, which may be formed of, for example, silicon oxide. Dielectric region 84 allows light to pass through, and may be used for a light beam to be transmitted from edge coupler 90 upwardly. In accordance with some embodiments, micro-lens (not shown) may be formed in the top portion of semiconductor substrate 74 to receive the light beam from an overlying optical fiber (if attached, not shown), or to transmit a light beam into an overlying optical fiber (not shown). In accordance with alternative embodiments, dielectric region 84 is not formed, and the dielectric layers 82 extends to the opposite edges of photonic die 72.

Photonic die 72 may include photonic devices such as waveguides, grating couplers, edge couplers, modulators, and/or the like. In accordance with some embodiments, dielectric layer 86 is formed, and may include silicon oxide, silicon nitride, or the like. A silicon layer may be formed on dielectric layers 82 and dielectric region 84. The silicon layer may be patterned, and may be used to form the waveguides 88 for the internal transmission of optical signals.

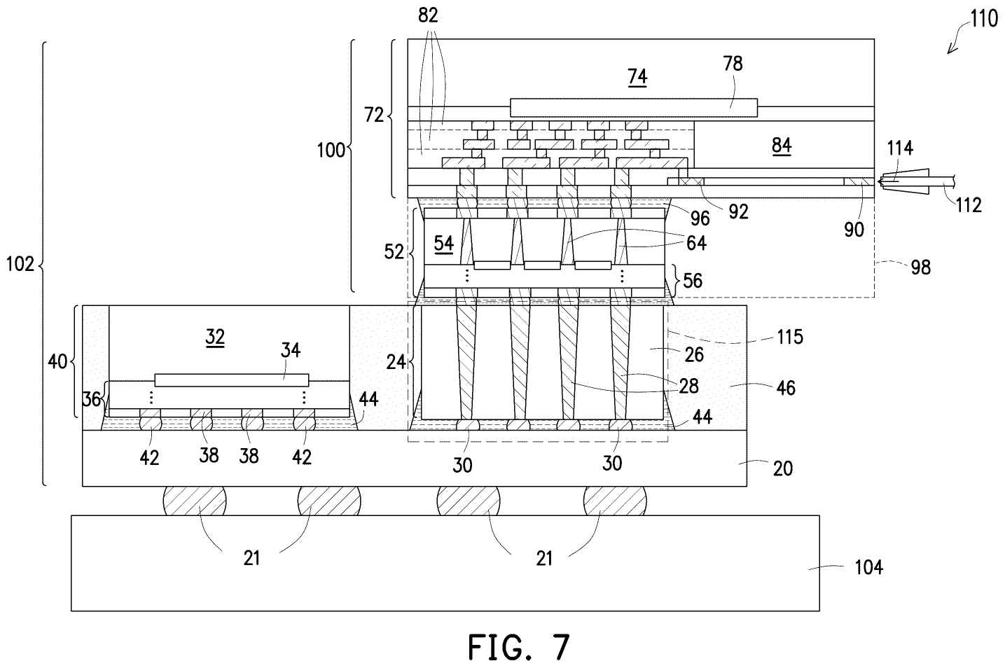

Edge coupler 90 may be formed to connect to one of waveguides 88. The edge coupler 90 may be used for receiving light from the respective light source or optical signal source (such as optical fiber 112 as shown FIG. 7), and transmitting the light to waveguide 88. Modulator(s) 92 may also be formed, and may be used for modulating the optical signals. It is appreciated that the illustrated structure in FIG. 6 is schematic, and photonic die 72 may include various other devices and circuits that may be used for processing and transmitting optical signals and electrical signals, which are also contemplated in accordance with some embodiments.

In accordance with some embodiments, underfill 96 is dispensed into the gap between electronic die 52 and photonic die 72. The respective process is illustrated as process 220 in the process flow 200 as shown in FIG. 11. A curing process is then performed to cure underfill 96. Underfill 96 may also include a base material such as a polymer, a resin, an epoxy, and/or the like, and filler particles (which may be formed of a dielectric material such as silica, aluminum oxide, or the like) in the base material.

In accordance with alternative embodiments, instead of bonding electronic die 52 to package 48′, and then bonding photonic die 72 to electronic die 52, electronic die 52 may be bonded to photonic die 72 first to form a photonic engine 100. The photonic engine 100 is then bonded to raising module 24. In accordance with these embodiments, an additional encapsulant 98, which may include a molding compound, may also be used to encapsulate electronic die 52. Accordingly, the photonic engine 100 may (or may not) include encapsulant 98, and the encapsulant 98 is shown as being dashed to indicate that it may or may not exist in the resulting package. Package 102 is thus formed. Package 102 includes photonic engine 100, and raising module 24 bonded to package component 20.

Referring to FIG. 7, package component 20 is further bonded to package component 104 in accordance with some embodiment. The bonding may be achieved through solder regions 21. In accordance with some embodiments, package component 104 may include an organic interposer, a printed circuit board, an additional package, or the like. The resulting package is referred to as photonic package 110.

FIG. 7 also illustrates an example usage of package 110, with optical signals being coupled into photonic die 72 through the edge coupler 90. Optical fiber 112 is mounted, and is aligned to edge coupler 90. A laser beam 114 may be projected out of optical fiber 112 and into edge coupler 90, which receives the optical signals and transmits the optical signals through waveguide 88.

FIGS. 8 through 10 illustrate some example structures of raising module 24 in accordance with various embodiments. The structures shown in FIGS. 8 through 10 may be the structure shown in region 115 in FIG. 7. The structure shown in FIG. 8 is essentially the same as shown in FIG. 7, with raising module 24 including through-vias 28 extending to the opposite sides (top side and bottom side) of substrate 26. In accordance with these embodiments, a single raising module 24 is used, and its height is designed as being great enough, so that raising module 24 has adequate mechanical strength to provide enough mechanical support to the overlying thin electronic die 52 from breaking,

In accordance with alternative embodiments, as shown in FIG. 9, raising module 24 includes substrate 120, and through-vias 28 formed in substrate 120. In accordance with some embodiments, substrate 120 is a semiconductor substrate, and thus is referred to as semiconductor substrate 120 hereinafter. In accordance with alternative embodiments, substrate 120 is also a dielectric substrate, and may be formed of a dielectric material, which may be an inorganic dielectric material or an organic dielectric material. For example, substrate 120 may be formed of or comprise a resin, an epoxy, silicon oxide, silicon nitride, silicon oxynitride, silicon carbonitride, a glass, or the like.

Substrate 120, when being a semiconductor substrate, may be formed of silicon in accordance with some embodiments. Through-vias 28 may also be formed of or comprise copper, nickel, tungsten, aluminum, or alloys thereof. Dielectric isolation regions 130 are formed to encircle through-vias 28, and to electrically decouple through-vias 28 from substrate 120. In accordance with some embodiments, raising module 24, although including semiconductor substrate, is also free from active devices and passive devices.

The raising module 24 as shown in FIG. 9 may include a top dielectric layer(s) 122 over substrate 120, and bottom dielectric layer(s) 126 under substrate 120. Redistribution lines (not shown) may be formed in dielectric layer(s) 126. Dielectric layers 122 and 126 may be formed of or comprise silicon oxide, silicon nitride, silicon oxynitride, silicon oxycarbide, low-k dielectric materials, and/or the like. In accordance with some embodiments, bond pads 124 and 128 are formed at the top surface and the bottom surface, respectively, of raising module 24, and may be formed of or comprise copper, titanium, nickel, aluminum, and/or the like.

In accordance with some embodiments, bond pads 124 are vertically aligned to corresponding bond pads 128, and are also vertically aligned to the respective connecting through-vias 28. Accordingly, raising module 24 functions to connect electrical signals/voltages vertically, but does not laterally reroute signals. In accordance with alternative embodiments, the metal lines/vias in dielectric layers 122 and 126 may laterally reroute the electrical signals, and the pitches of bond pads 128 may be greater than or smaller than the pitches of bond pads 124.

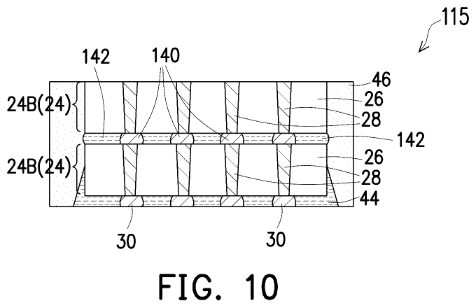

FIG. 10 illustrates the use of a plurality of raising module 24 in accordance with some embodiments. In an illustrated example, two raising modules 24A and 24B (referred to as raising modules 24 collectively) are stacked. In accordance with other embodiments, more raising modules such as three, four or more raising modules 24 may be stacked. The plurality of raising modules 24 may be bonded through solder regions 140. In accordance with some embodiments, underfill(s) 142 may be disposed between neighboring raising modules 24 to protect the solder regions 140. In accordance with alternative embodiments, no underfill is disposed between neighboring raising modules 24. The encapsulant 46 in accordance with these embodiments may be a molding underfill, which is filled into the gaps between neighboring raising modules 24. The encapsulant 46 also encapsulates raising modules and device die 40 (FIG. 7) therein.

It is appreciated that adopting multiple raising modules 24 may increase the total thickness of encapsulant 46, and more raising modules 24 in combination with the thicker encapsulant 46 may provide higher mechanical strength to support the overlying electronic die 52, so that electronic die 52 may be thin without the concern of breaking. In addition, since through-vias 28 may have a tapered profile, a thicker raising module 24 may result in the width (or diameter) of through-vias 28 to be increased, which means the pitch P1 (FIG. 5) of the through-vias 28 may have to be greater than the pitch P2 of the through-vias 64 in electronic die 52. By replacing a single thick raising module 24 with a plurality of thinner raising modules 24, the through-vias 28 in the plurality of thinner raising modules 24 may have smaller pitches, and the smaller pitches may match the pitch P2 of the overlying through-vias 64.

In accordance with some embodiments, each of the raising modules 24A and 24B may have the structure, and adopt the materials as discussed referring to FIGS. 1, 8, and 9. Furthermore, the structures of the plurality of raising modules 24 may be the same or different from each other. For example, each of raising modules 24A and 24B may adopt any of the structures shown and discussed referring to FIGS. 1, 8, and 9 in any combination. Furthermore, the pitches of the through-vias 28 in the plurality of raising module 24 may be the same or different from each other. In accordance with some embodiments, the through-vias 28 in the plurality of raising modules (such as raising modules 24A and 24B) are vertically aligned.

In above-illustrated embodiments, some processes and features are discussed in accordance with some embodiments to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By bonding a raising module to a package substrate, encapsulating the raising module, and bonding an electronic die to the raising module, the electronic die may be raised in height, for example, to the level higher than the device dies that are also bonded to the package component. This makes the photonic die to be exposed more, and makes it more convenient for the photonic die to be aligned to optical devices. For example, if the raising module is not used, the photonic die may be too close to the underlying package component since the electronic die is thin, and this makes the alignment and the mounting of the optical fiber to be very difficult.

In addition, by adopting raising module and encapsulating the raising module in an encapsulant, a mechanically stronger structure is provided for the thin electronic die to bonded on. It is less likely for the electronic die to break. Also, since the electronic die is not prone to breakage, there is no need to make the electronic die thicker in order to make it stronger, while the thicker electronic die will adversely result in the through-vias therein to be formed larger, and in turn requires the electronic die to be formed larger.

In accordance with some embodiments, a method comprises bonding a first module over a package component, wherein the first module comprises a substrate; and through-vias penetrating through the substrate; molding the first module in a molding compound; bonding an electronic die on the first module; and bonding a photonic die over the electronic die. In an embodiment, the molding the first module comprises disposing the molding compound on the first module; and performing a planarization process to reveal both of the through-vias and the substrate.

In an embodiment, the first module is bonded over the package component through a first plurality of solder regions, with the first plurality of solder regions physically contacting bottom ends of the through-vias; and the electronic die is bonded over the first module through a second plurality of solder regions, with the second plurality of solder regions physically contacting top ends of the through-vias. In an embodiment, the substrate in the first module is a dielectric substrate. In an embodiment, the method further comprises bonding a second module over the package component, wherein the second module is stacked with the first module. In an embodiment, the second module is bonded between the first module and the package component.

In an embodiment, the first module and the second module have an identical structure. In an embodiment, the through-vias in the first module are vertically aligned to the through-vias in the second module with a one-to-one correspondence. In an embodiment, the method further comprises bonding a device die over the package component, wherein the device die is also molded in the molding compound. In an embodiment, the first module is free from active devices and passive devices. In an embodiment, the first module is free from horizontal conductive lines.

In accordance with some embodiments, a structure comprises a package substrate; a first module over and electrically coupling to the package substrate, wherein the first module comprises a substrate; and through-vias penetrating through the substrate; a molding compound molding the first module; an electronic die over and bonding to the first module, wherein the electronic die is electrically coupled to the package substrate through the first module; and a photonic die over and signally coupling to the electronic die.

In an embodiment, first top surfaces of the through-vias are coplanar with a second top surface of the substrate, and wherein first bottom surfaces of the through-vias are coplanar with a second bottom surface of the substrate. In an embodiment, the first module is free from horizontal conductive lines therein. In an embodiment, a first top surface of the first module is coplanar with a second top surface of the molding compound. In an embodiment, the structure further comprises a second module bonded between the first module and the package substrate. In an embodiment, the first module is identical to the second module.

In accordance with some embodiments, a structure comprises a module comprising a dielectric substrate formed of a homogeneous dielectric material; and a plurality of metal posts penetrating through the dielectric substrate; a first plurality of solder regions underlying and contacting bottom surfaces of the plurality of metal posts; a second plurality of solder regions overlying and contacting top surfaces of the plurality of metal posts; an electronic die over and bonding to the second plurality of solder regions; and a photonic die over and bonding to the electronic die.

In an embodiment, the structure further comprises an encapsulant, wherein the module is in the encapsulant. In an embodiment, the structure further comprises a first underfill, wherein the first plurality of solder regions are in the first underfill; and a second underfill, wherein the second plurality of solder regions are in the second underfill.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a first module over a package component, wherein the first module comprises:
a substrate; and
through-vias penetrating through the substrate;
molding the first module in a molding compound, wherein the molding the first module comprises:
disposing the molding compound on the first module; and
performing a planarization process to reveal both of the through-vias and the substrate;
bonding an electronic die on the first module; and
bonding a photonic die over the electronic die,
wherein first module is bonded over the package component through a first plurality of solder regions, with the first plurality of solder regions physically contacting bottom ends of the through-vias, and
wherein the electronic die is bonded over the first module through a second plurality of solder regions, with the second plurality of solder regions physically contacting top ends of the through-vias.
